(19) United States
(12) Patent Application Publication
(10) Pub. No.: US 2026/0372145 A1
(43) Pub. Date: Nov. 19, 2026

(54) MONOLITHIC CORE SUBSTRATES

(71) Applicant: Advanced Micro Devices, Inc., Santa Clara, CA (US)

(72) Inventors: Prithwish CHATTERJEE, Austin, TX (US); Sri Ranga Sai BOYAPATI, Austin, TX (US); Robert Grant SPURNEY, Austin, TX (US); Deepak Vasant KULKARNI, Austin, TX (US); William James LAMBERT, Phoenix, AZ (US); Raja SWAMINATHAN, Austin, TX (US)

(21) Appl. No.: 19/423,717

(22) Filed: Dec. 17, 2025

Related U.S. Application Data
(60) Provisional application No. 63/805,763, filed on May 14, 2025.

(51) Int. Cl. H10W 70/68; H10W 72/00; H10W 74/10

(52) U.S. Cl. CPC H10W 70/682; H10W 72/823; H10W 74/114

(57) ABSTRACT

Integrated circuit (IC) modules having one or more IC devices embedded into a monolithic substrate core are provided, along with electronic devices and chip packages having the same. The monolithic core is configured to allow IC devices of varying profile and thickness to be embedded therein when the core has a thickness in excess of the height of the embedded IC device.

### CROSS REFERENCE TO RELATED APPLICATIONS

This application claims benefit of United States Provisional Patent Application No. 63/805,763, filed May 14, 2025, which is incorporated by reference in its entirety.

### TECHNICAL FIELD

Embodiments of the present disclosure generally relate to embedding one or more integrated circuit (IC) devices into a monolithic substrate core, and chip packages having the same. In particular, some embodiments relate to one or more IC devices disposed a cavity of a monolithic core.

### BACKGROUND

Data center graphic and central processing units have seen a significant increase in thermal design power (TDP), increasing from 550-750 W to 2.5 KW, with projections reaching approximately 5 KW in the near future. This substantial growth in power density necessitates the development of advanced solutions to effectively manage the increased electrical and thermal loads.

To address electrical challenges, particularly those related to efficiency, a specialized class of active components must be integrated into the architecture. These components can modulate power requirements and support dynamic voltage scaling by leveraging active silicon devices. This capability allows processors to adjust voltage levels in real time based on workload demands, optimizing power consumption during periods of low activity and enhancing performance during peak operations. However, such components require physical space, which is limited; therefore, embedding them within the core presents an attractive alternative. However, embedding active and passive components present substantial challenges. Industry trends currently demand that embedded components precisely match the core thickness, requiring intricate and precise design and manufacturing techniques.

The pursuit of higher compute power for next generation GPUs will inevitably lead to larger, more complex die designs, necessitating a significant increase in the number of integrated voltage regulators. Consequently, manufacturing processes must tackle the challenge of warpage by employing substrates with very thick cores, while also ensuring that component thickness is compatible.

At present, manufacturing capabilities are constrained by a thickness cap of about 800 micrometers, which limits the ability to embed extremely thick components. Moreover, next generation GPU products require a substantial increase in embedded components, expanding to approximately 100s of cavities for active silicon and passive components.

The inventors have recognized limitations the need for innovative solutions in embedding and materials engineering to accommodate the rising demands of power density and component integration in advanced computing systems.

### SUMMARY

Integrated circuit (IC) modules having one or more IC devices embedded into a monolithic substrate core are provided, along with electronic devices and chip packages having the same. The monolithic core is configured to allow IC devices of varying profile and thickness to be embedded therein when the core has a thickness in excess of the height of the embedded IC device.

This novel monolithic architectural design and a detailed process flow enables manufacturing of advanced substrate types. This innovation is designed specifically to address and alleviate the existing challenges associated with integrating components of varying profiles into a substrate, where traditional methods struggle to accommodate mismatched core and component thicknesses. This unique monolithic structure and method provides a path to improved manufacturing flexibility and increased component compatibility, ultimately enhancing product reliability and performance. The monolithic architecture leverages cutting-edge techniques, such as controlled drilling and SAP-compatible materials, to maintain structural integrity and optimize thermal and electrical performance across diverse applications.

This innovative solution leverages the use of a monolithic core with a low CTE material, allowing the integration of components with varied profiles and thicknesses without requiring additional structural layers. The monolithic architecture enables vertical connections through precise via drilling within the monolithic core, supporting robust electrical pathways and patterning options.

Component integration challenges are met by facilitating integration within a monolithic core, which resolves the challenge of aligning component and core thickness, which is important for accommodating recent increases in substrate size. This approach removes the dependency on industry partners who lack the capability to produce extremely thick components.

Scalability and future proofing are enabled by the monolithic architecture, which allows for future increases in core thickness without necessitating thicker components (>1.5 mm). This flexibility supports evolving technological requirements while keeping component costs steady.

Manufacturing efficiency is improved by the monolithic design of the reduced need for multiple prepreg layers, minimizing thermal expansion issues and decreasing the need for extensive laser drilling. This enables the use of alternative core suppliers, potentially lowering costs through competitive pricing.

Power delivery is enhanced due to the potential increase in side-wall copper, significantly improving power delivery capabilities. Additionally, more reliable fully filled copper vias are obtained, unlike other concepts using conductive paste, which are limited in power delivery and pose greater electromigration risks.

Higher throughput and yield are achieved due to linear increases in core thickness, which improves embedding efficiency, reduces costs, and enhances overall assembly yield. This alleviates pressure on existing substrate technologies by avoiding the high costs associated with laser ablation of thick cores.

This comprehensive architecture not only tackles the current component integration and structural consistency challenges, but also offers a cost-effective, adaptable framework for future technological advancements, with improved electrical and power delivery reliability.

In one example, the IC module includes a monolithic core and an IC device. The monolithic core includes a first face and a second face, where the cavity is open through the first and second faces of the monolithic core. The IC device is disposed in the cavity of the monolithic core. The IC device has a height that is equal to or less than a distance defined between the first and second faces of the monolithic core.

In one example, an integrated circuit (IC) modules is provided that includes a substrate core, an IC device, and mold compound. The substrate core has a first face and a second face. A cavity is formed in the substrate core and is open through the first and second faces of the substrate core. The IC device is disposed in the cavity of the substrate core. The IC device has a height defined between a first face and a second face of the IC device that is less than a distance defined between the first and second faces of the substrate core. The mold compound is also disposed in the cavity of the substrate core. The mold compound has a first surface that is substantially coplanar with the first faces of the substrate core and the IC device. The mold compound has a second surface that is substantially coplanar with the second face of the substrate core.

In another example, a chip package is provided. The chip package includes substrate core, an IC device, mold compound, first built-up layers, and an integrated circuit (IC) die. The substrate core has a first face and a second face. A cavity is formed in the substrate core and is open through the first and second faces of the substrate core. The IC device is disposed in the cavity of the substrate core. The IC device has a first face and a second face. A height of the IC device is less than a distance defined between the first and second faces of the substrate core. The mold compound is disposed in the cavity of the substrate core. The mold compound has a first surface that is substantially coplanar with the first faces of the substrate core and the IC device. The mold compound has a second surface that is substantially coplanar with the second face of the substrate core. The first built-up layers are formed on the first face of the substrate core and have substrate routing circuitry. The IC die is disposed on the first built-up layers. The IC die has functional circuitry that is coupled to the IC device through the first built-up layer routing circuitry.

In yet another example, a chip package is provided. The chip package includes substrate, an integrated voltage regulator, mold compound, an integrated circuit (IC) die, and a first plurality of conductive vias. The substrate has a core, the core having a cavity. The IC device is disposed in the cavity and laterally overlapped with integrated voltage regulator. The core of the substrate has a thickness that is 2 or more times greater than a height of the integrated voltage regulator. The first plurality of conductive vias extend through the mold compound to a face of the integrated voltage regulator that faces away from the IC die.

Other examples are provided in below.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 is a schematic side view one example of an electronic device that includes a chip package having a monolithic core substrate, the chip package including an integrated circuit (IC) device embedded in the monolithic core of the substrate.

FIG. 2 is a schematic side view one example of the substrate of FIG. 1.

FIG. 3 is a block diagram of a method for fabricating a substrate having one or more IC devices embedded in the monolithic core of the substrate.

FIGS. 4A-4F are schematic side views of a substrate having an embedded IC device during various stages of fabrication.

FIG. 5 is a block diagram of another method for fabricating a substrate having two or more IC devices embedded in the monolithic core of the substrate.

FIGS. 6A-6F are schematic side views of another substrate having embedded IC devices during various stages of fabrication.

To facilitate understanding, identical reference numerals have been used, where possible, to designate identical elements that are common to the figures, and a second-case letter added where the elements are substantially the same. It is contemplated that elements of one embodiment may be beneficially incorporated in other embodiments.

### DETAILED DESCRIPTION

Disclosed is innovative monolithic substrate architecture that facilitates the integration of components with varying profiles and thicknesses, enhancing design flexibility and allowing for more versatile applications. This monolithic substrate architecture is enabled through the use of a cavity fill which has a low coefficient of thermal expansion (CTE) material for better reliability as well have the ability to mechanically drilled. The material is compatible with Semi-Additive Process (SAP) and electroless copper plating (E-less), ensuring seamless integration within the substrate.

Displacement-controlled drilling can be used to form mechanically through-holes (MTH) within the low CTE material comprising the mold compound. The MTH maintains compatibility with E-less processes used to form conductive vias. The MTH can be precisely drilled, thus, establishing robust vertical connections for two-sided component integration while ensuring comprehensive electrical connectivity.

The monolith substrate architecture also provides flexible power delivery options. The monolith substrate architecture provides the capability to create either fully filled MTH or side-wall plated architectures, tailored to meet specific power delivery requirements and operational demands. The monolith substrate architecture significantly enhances the ability to integrate diverse IC component types while maintaining high performance and reliability.

The monolith substrate architecture leverages the use of a monolithic core with a low CTE material, which allows the integration of IC components with varied profiles and thicknesses without requiring additional structural layers. The monolith substrate architecture enables vertical connections through precise via drilling within the monolithic core, supporting robust electrical pathways and patterning options.

Component integration challenges are addressed by facilitating integration within a monolithic core. The monolith substrate architecture resolves the challenge of aligning IC component and core thickness, which is important for accommodating recent increases in substrate size. The monolith substrate architecture approach also removes the dependency on limited amount of suppliers who have the capability to produce extremely thick components. The monolith substrate architecture enables the use of alternative core suppliers, opening the possibility of sourcing alternative core suppliers and lowering costs.

The monolith substrate architecture is scalable, allowing for future increases in core thickness without necessitating thicker components (>1.5 mm). This flexibility supports evolving technological requirements while keeping component costs steady.

The monolith substrate architecture provides improved manufacturing efficiency by reducing the need for multiple prepreg layers, minimizing thermal expansion issues and decreasing the need for extensive laser drilling.

The monolithic architecture provides enhanced power delivery and allows for the potential increase in side-wall copper, which significantly improving power delivery capabilities. Additionally, the monolith substrate architecture provides more reliable fully filled copper vias, unlike other concepts using conductive paste, which are limited in power delivery and pose greater electromigration risks.

Higher throughput and yield are achieved due to linear increases in core thickness, which improves embedding efficiency, reduces costs, and enhances overall assembly yield. The monolith substrate architecture alleviates pressure on existing substrate technologies by avoiding the high costs associated with laser ablation of thick cores.

The monolith substrate architecture not only tackles the current IC component integration and structural consistency challenges, but also offers a cost-effective, adaptable framework for future technological advancements, with improved electrical and power delivery reliability.

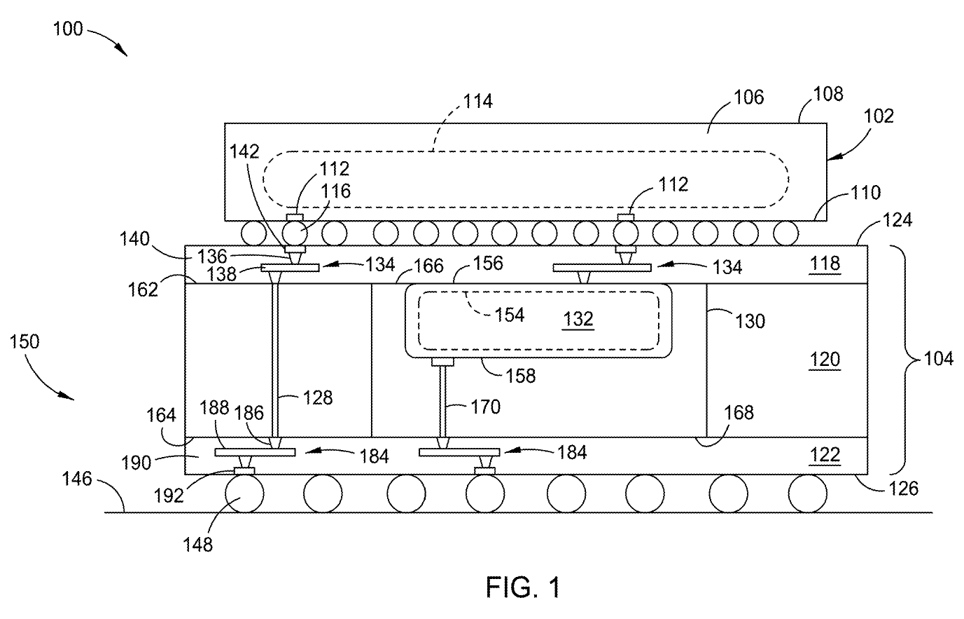

Turning now to FIG. 1, a schematic side view one example of an electronic device 150 that includes a chip package 100 having a substrate 104 is provided. The chip package 100 includes at least one or more integrated circuit (IC) devices 132 embedded in the monolithic core 120 of the substrate 104. The electronic device 150 includes the chip package 100 mounted on a printed circuit board 146. The chip package 100 may be mounted on a printed circuit board (PCB) 146 using a socket, wire bonding, solder balls, or other suitable technique. In the example illustrated in FIG. 1, the chip package 100 electrically and mechanically coupled to the PCB 146 using solder balls 148.

The chip package 100 includes one or more IC dies 102 disposed on a substrate 104. Although only one IC die 102 is illustrated in FIG. 1, one or more IC dies maybe vertically stacked one on top of the other, and/or laterally stacked side-by-side on the substrate 104.

The body 106 of the IC die 102 includes a first face 108 and a second face 110. The body 106 of the IC die 102 includes functional circuitry 114. The functional circuitry 114 is disposed within the body 106 of the IC die 102 and may include compute and/or logic circuitry. In one example, the functional circuitry 114 is configured as a processor, such as a central processing unit (CPU) or a graphics processing unit (GPU). The functional circuitry 114 terminates at a contact pad 112 exposed on the second face 110 that faces the substrate 104.

The second face 110 of the IC die 102 is electrically and mechanically coupled to the substrate 104. In one example, interconnects 116 coupled the contact pads 112 exposed on the second face 110 of the IC die 102 to the routing circuitry of the substrate 104. The interconnects 116 may be solder balls, or alternatively, the interconnects maybe a hybrid bonding layer formed on the substrate 104.

The substrate 104 depicted in FIG. 1 is configured as a package substrate. However, the substrate 104 may also be configured an interposer disposed between a package substrate 104 and the IC die 102.

The substrate 104 includes a single monolithic core 120 sandwiched between a first built-up layer 118 and a second built-up layer 122. The substrate 104 has a first face 124 and a second face 126. The first face 124 faces the second face 110 of the IC die 102. The second face 126 faces away from the IC die 102. One side of the first built-up layer 118 forms the first face 124 of the substrate 104, while the opposite side of the first built-up layer 118 is disposed in contact with the core 120. Similarly, one side of the second built-up layer 122 forms the second face 126 of the substrate 104, while the opposite side of the second built-up layer 122 is disposed in contact with the core 120.

The core 120 of the substrate 104 is generally formed from an inorganic material, such as silicon, ceramic, glass reinforced plastic, and the like. The core 120 of the substrate 104 may alternatively be formed from other rigid materials. The core 120 includes a first face 162 and a second face 164. The first built-up layer 118 is disposed on the first face 162 of the core 120. The second built-up layer 122 is disposed in contact with the second face 164 of the core 120.

A cavity 130 is formed in the core 120. The cavity 130 may be in the form of a recess that extends from the first face 162 into the core 120. In the example depicted in FIG. 1, the cavity 130 extends from the first face 162 and exits the second face 164 of the core 120, thus forming a passage completely through the core 120.

As briefly stated above, at least one IC device 132 is disposed in the cavity 130. Alternatively, more than one IC devices 132 may be disposed in the cavity 130. The IC device 132 does not extend beyond the faces 162, 164 of the core 120. In one example, the IC device 132 is a pre-fabricated unitary component that secured in the cavity 130. The IC device 132 generally has a height that is less than a thickness of the core 120. In one example, the thickness of the core 120 is greater than about 1000 µm. In another example, the thickness of the core 120 is greater than about 1600 µm. The height of the IC device 132 is less than or equal to about 800 µm, such as less than or equal to 750 µm. In one example, the thickness of the core 120 is at least 1.25 or more times the height of the IC device 132. In another example, the thickness of the core 120 is at least 2.0 or more times the height of the IC device 132.

Continuing to refer to FIG. 1, a plurality of vias 128 are disposed through the core 120. The vias 128 are filled with a conductive material, such as copper. Although only two vias 128 are illustrated in the core 120 depicted in FIG. 1, it is to be understood that the core 120 may include many vias 128. The vias 128 through the core 120 may be laser drilled or formed by another suitable technique. The vias 128 are filled with a conductive material, such as copper, and may be utilized to transmit/connect ground, power, and/or signals through the core 120. The vias 128 are ultimately coupled to the functional circuitry 114 of the IC die 102 through first built-up layer routing circuitry 134 of the first build-up layer 118. In other examples, one or more of the vias 128 may be configured as thermally conductive pillars, such as copper or other metal pillars, whose primarily function is to transmit heat through the core 120. Such vias 128 configured as thermally conductive pillars are not coupled to the functional circuitry 114 of the IC die 102.

The first built-up layer 118 generally includes patterned metal layers formed between dielectric layers 140. Although the dielectric layers 140 are illustrated in FIG. 1 as a single block of material, at least 3 or more layers of dielectric material comprise the dielectric layers 140 of the first built-up layer 118. The patterned metal layers are interconnected to form the first built-up layer routing circuitry 134. The first built-up layer routing circuitry 134 is generally formed by vias 136 and lines 138. The first built-up layer routing circuitry 134 generally terminates at a contact pad 142 exposed on the first face 124 of the substrate 104. In one example, an interconnect 116, such as a microbump, is utilized to connect the contact pad 142 of the substrate 104 with the contact pad 112 of the IC die 102, thus electrically connecting the functional circuitry 114 of the IC die 102 to the first built-up layer routing circuitry 134 of the substrate 104. In another example, the interconnect 116 maybe a hybrid bonding layer that electrically connects the contact pads 112, 142 while bonding the second face 110 of the IC die 102 to the first face 124 of the substrate 104.

The first built-up layer routing circuitry 134 may be coupled to the vias 128 formed through the core 120 to provide ground, power, and/or signals through the first built-up layer 118 to the functional circuitry 114 of the IC die 102. The first built-up layer routing circuitry 134 may optionally be utilized to couple to the vias 128 configured as heat transfer pillars to route heat out of the substrate 104. The first built-up layer routing circuitry 134 is also coupled to the IC device 132 disposed in the core 120 to provide ground, power, and/or signals between the IC device 132 and the to the functional circuitry 114 of the IC die 102.

The second built-up layer 122 generally includes patterned metal layers formed between dielectric layers 190. Although the dielectric layers 190 are illustrated in FIG. 1 as a single block of material, at least 3 or more layers of dielectric material comprise the dielectric layers 190 of the second built-up layer 122. The patterned metal layers are interconnected to form second built-up layer routing circuitry 184. The second built-up layer routing circuitry 184 is generally formed by vias 186 and lines 188. One end of the second built-up layer routing circuitry 184 is connected to the vias 128 formed through the core 120 of the substrate 104. The second built-up layer routing circuitry 184 may be coupled to the first built-up layer routing circuitry 134 through the vias 128 formed through the core 120 to provide ground, power, and/or signals through the substrate 104 to the functional circuitry 114 of the IC die 102. One end of the second built-up layer routing circuitry 184 may optionally terminate and be coupled the vias 170. The second built-up layer routing circuitry 184 are coupled to the circuit elements (e.g., the active and/or passive devices) of the IC device 132 through the vias 170. The other end of the second built-up layer routing circuitry 184 terminates at a contact pad 192 exposed on the second face 126 of the substrate 104. In one example, a solder ball 148 1s utilized to connect the contact pad 192 of the substrate 104 with a contact pad of the PCB 146, thus forming the electronic device 150 and electrically connecting the functional circuitry 114 of the IC die 102 (and/or circuit elements of the IC device 132) to the circuitry of the PCB 146.

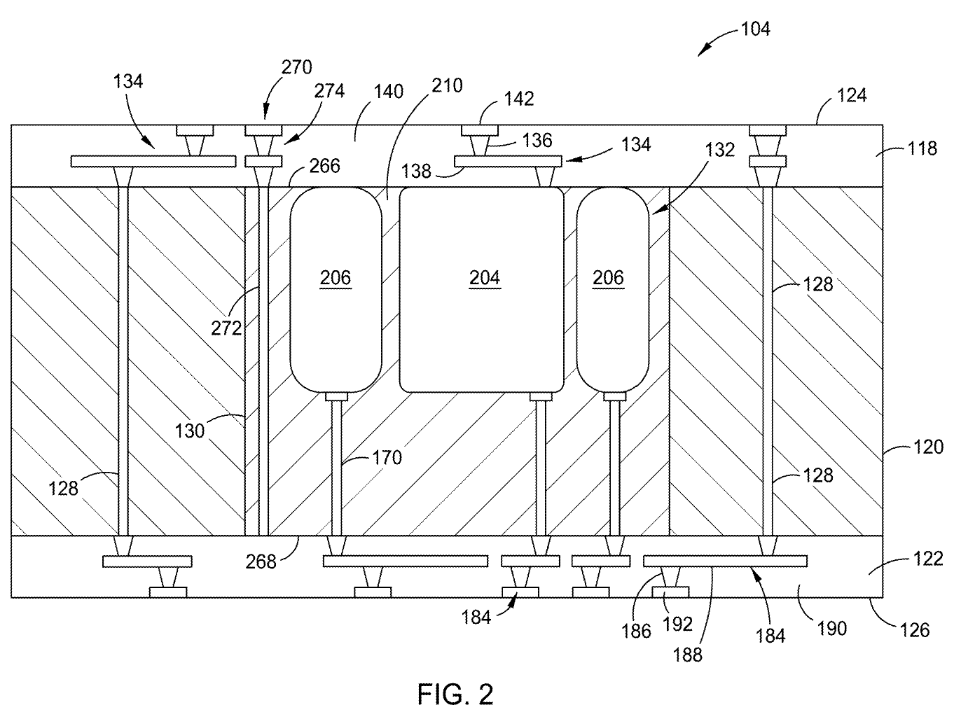

FIG. 2 is a schematic side view one example of the substrate 104 of FIG. 1. In contrast to the example depicted in FIG. 1 that illustrates a single IC device 132 embedded in the substrate 104, the example depicted in FIG. 2 illustrates a plurality of IC devices 132 disposed in the core 120 of the substrate 104. When multiple IC devices 132 are disposed in the core 120 of the substrate 104, the IC devices 132 may be the same or different type of IC device 132. In one example, the IC device 132 is a pre-fabricated unitary component that is inserted into the cavity 130 of the substate 104, such as in the form of a chiplet.

The IC device 132 has a first face 156 and a second face 158. The first face 156 of the IC device 132 faces the first built-up layers 118 of the substrate 104 and the IC die 102. The second face 158 of the IC device 132 faces the second built-up layers 122 of the substrate 104. Optionally, the IC device 132 may be utilized flipped upside down. At least one of the faces of the IC device 132 includes contact pads for establishing electrical connection with the internal circuitry of the IC device 132. If communication with the internal circuitry of the IC device 132 is only desired from the side of the IC device 132 facing the first built-up layers 118, then contact pads are only needed on the first face 156 of the IC device 132 to connect with the first build-up layer circuitry 134. Similarly, if communication with the internal circuitry of the IC device 132 is only desired from the side of the IC device 132 facing the second built-up layers 122, then contact pads are only needed on the second face 158 of the IC device 132 for connection with the vias 170. If communication with the internal circuitry of the IC device 132 is desired from both sides of the IC device 132 that the first and second built-up layers 118, 122, then contact pads are present on both the first and second faces 156, 158 of the IC device 132.

The IC device 132 may be configured as either an active device 204 or a passive device 206. The active device 204 is a small, specialized, and independent integrated circuit chiplet designed to perform a specific function, such as processing, memory, or I/O. The active device 204 has circuitry configured to perform as an integrated voltage regulator (IVR), an amplifier, or logic transistors, among others. The passive device 206 has circuitry configured to perform as capacitors, inductors, resistors, and the like. The inductors may be air core inductors, magnetic core inductors, or other type of inductor.

In the example depicted in FIG. 2, the IC devices 132 embedded in the core 120 of the substrate 104 include at least one active device 204 and at least one passive device chiplet 206. The active device 204 includes IVR circuitry. The passive devices are configured as inductors or capacitors.

The IC devices 132 are retained in the cavity 130 by mold compound 210. The mold compound 210 has a first face 266 that faces the IC die 102 and a second face 268 that faces away from the IC die 102. The first face 266 of the mold compound 210 is coplanar with the first face 162 of the core 120. The second face 268 of the mold compound 210 is coplanar with the second face 164 of the core 120. The mold compound 210 may be an epoxy, polyurethane, silicone, or other suitable potting compound. The mold compound 210 is generally selected to have a low coefficient of thermal expansion (CTE), such as less than about 10 ppm/degree Celsius.

In one example, the mold compound 210 is selected to have good thermal conductivity (i.e., thermal conductivity greater than about 1.0 W/m·K) such that heat is readily passed out of the IC device 132. For example, the mold compound 210 may be a thermally conductive epoxy, thermally conductive polyurethane, or thermally conductive silicon. Thermally conductive mold compounds 210 may include aluminum oxide, boron nitride or other material that increases the thermal conductivity above the base compound.

To further enhance heat transfer away from the active device 204 and out of the monolithic core 210 of the substrate 104, one or more thermally conductive pillars 272 may be disposed through the mold compound 210. The via 272 may be formed from copper or other thermally conductive material, such as other metals or carbon-based materials. The via 272 may be part of a thermal via 270. The thermal via 270 includes a via stack 274 formed through the first module built-up layers 212 which is connected to the via 272. Although only one thermal via 270 is illustrated in FIG. 2, it is contemplated that the substrate 104 may include multiple thermal vias 270 to enhance heat transfer away from the active device 204, thus ensuring the performance and reliability of the active device 204. The vias 272 may optionally be used to connect with the first build-up layer circuitry 134 of the first build-up layer 118, and ultimately with the functional circuitry 154 of the IC die 102.

The vias 170 are also disposed through the mold compound 210. One end of vias 170 is coupled to the second built-up layer routing circuitry 184 of the second built-up layer 122. The other end of the 170 to the circuit elements (e.g., the active and/or passive circuitry) of the IC device 132.

The vias 170 are formed in the mold compound 210 after the mold compound 210 has hardened. The vias 170 form mechanically through-holes (MTH) within the low CTE material comprising the mold compound 210. The MTH are generally formed by mechanical drilling or laser drilling, and maintains compatibility with E-less processes used to form conductive vias. The MTH vias 170 are precisely drilled and provide robust vertical connections.

The vias 170 are made conductive by filling or coating the via 170 with an electrically conductive material, for example copper. Copper may completely fill the vias 170, or be plated around the sidewalls of the vias 170.

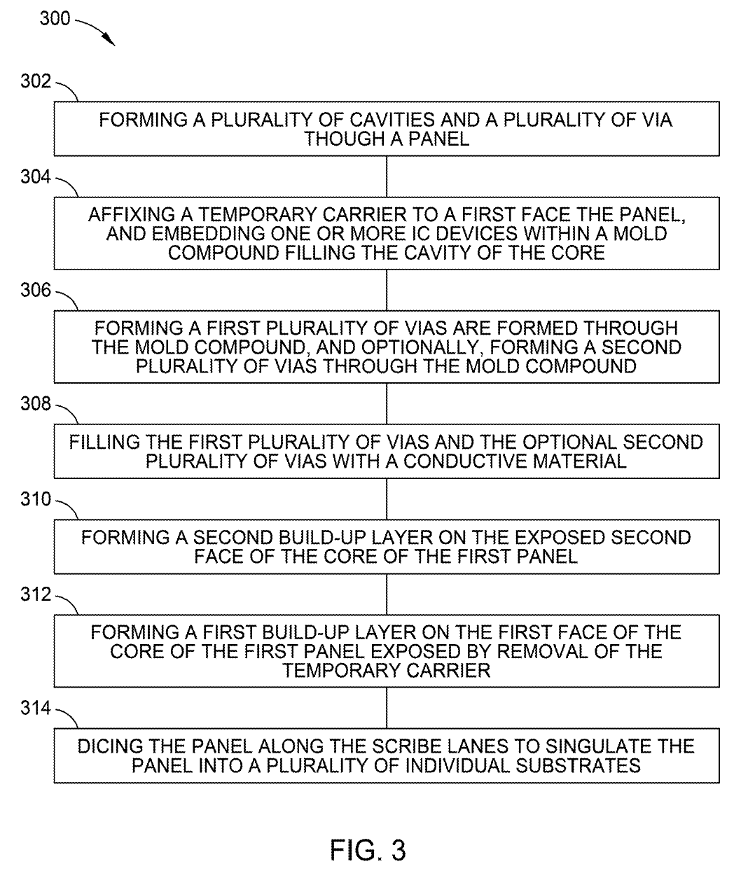

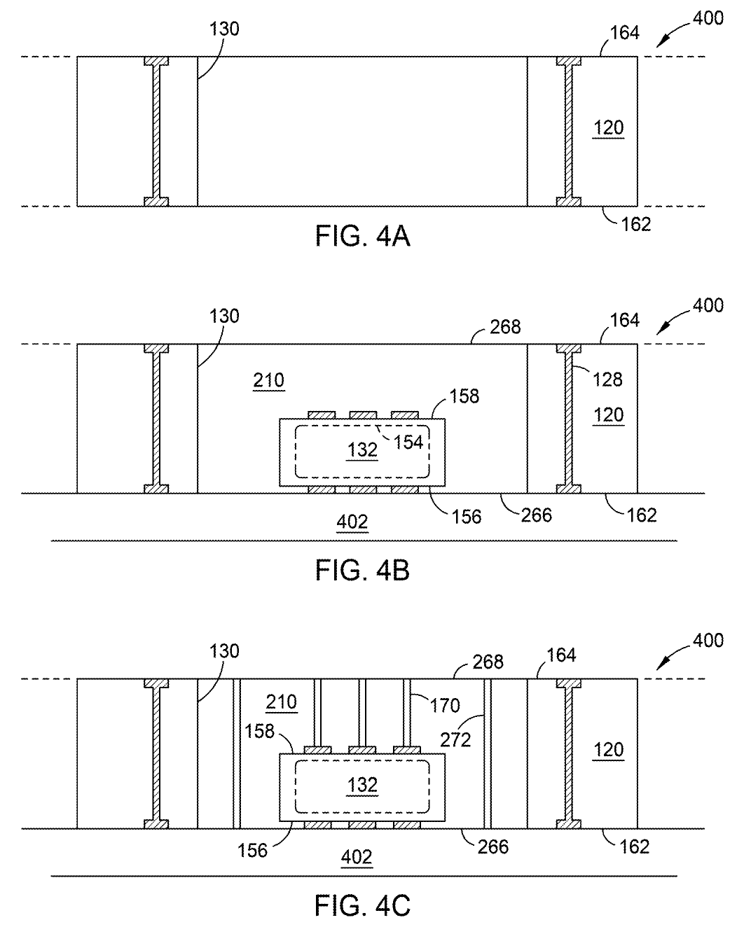

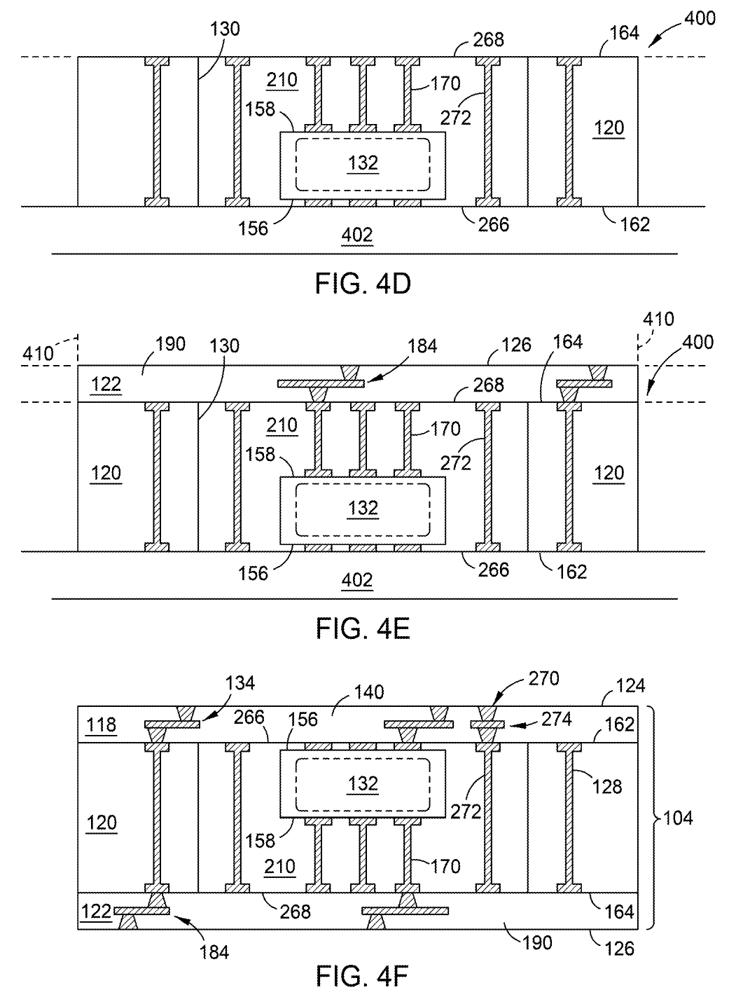

FIG. 3 is a block diagram of a method 300 for fabricating a substrate, such as but not limited to the substrate 104 depicted in FIGS. 1-2 that have one or more IC devices 132 embedded in a monolithic core 120 of the substrate 104. FIGS. 4A-4F are schematic side views of the substrate 104 having an embedded IC device 132 during various stages of fabrication in accordance with the method 300.

The method 300 begins at operation 302 by forming a plurality of cavities 130 though a core panel 400, as illustrated in FIG. 4A. A plurality of substrates 104 are singulated from the core panel 400, as later described below. The core panel 400 include faces 162, 164, that later become the faces of the core 120 of the substrate 104 after singulation of the core panel 400. Although only one cavity 130 is illustrated in FIG. 4A, it is to be understood that the core panel 400 extends to the laterally as represented by the dashed lines extending from the faces 162, 164, and that the additional cavities are formed in the same manner shown.

Also at operation 302, a plurality of vias 128 may be formed through the panel 128. The vias 128 are filled with a conductive material, such as copper, at operation 302 or other subsequent operation. Optionally, the plurality of vias 128 may be formed and/or filled at a different stage of fabrication.

At operation 304, a temporary carrier 402 is affixed to the first face 162 the core panel 400, and one or more IC devices 132 are embedded within the mold compound 210 filling the cavity 130 of the core 120, as shown in FIG. 4B. The temporary carrier 402 may be an aluminum plate or other rigid plate. The IC device 132 may be first attached to the temporary carrier 402 by die attach tape or other temporary adhesive within the cavity 130 prior to filling the cavity 130 and partially encapsulating the IC device 132 with the mold compound 210. Contact pads are also formed on the terminals of the IC device 132 prior to encapsulating the IC device 132 with the mold compound 210.

The one or more IC devices 132 may be active and/or passive devices (204, 206). One IC device 132 is shown in the cavity 130 depicted in FIG. 4B. Mold compound 210 is disposed in the cavities 130 to cover the IC devices 132.

At operation 306, a first plurality of vias 170 are formed through the mold compound 210, as illustrated in FIG. 4C. The first plurality of vias 170 may be mechanically through-holes (MTH), for example formed through the mold compound 210 by drilling or other suitable technique. The vias 170 extend from the second face 268 of the mold compound 210 to the contact pads formed on the second face 158 of the IC devices 132.

Optionally at operation 306, a second plurality of vias 272 are formed through the mold compound 210, as illustrated in FIG. 4C. The second plurality of vias 272 may be formed by any suitable technique. The vias 272 extend from the second face 268 of the mold compound 210 to the first face 266 of the mold compound 210, forming a passage completely through the mold compound 210.

At operation 308, the first plurality of vias 170 and the optional second plurality of vias 272 are filled with a conductive material, as illustrated in FIG. 4D. The vias 170, 272 may be completely filed with copper or other conductive material. In one example, the sidewalls of the vias 170 and optionally the sidewalls of the vias 272, are plated.

The conductive filled vias 170 are electrically and mechanically coupled to the contact pads exposed on the second face 158 of the IC device 132. Thus, the conductive filled vias 170 are electrically coupled to the functional circuitry of the IC device 132.

At operation 310, a second build-up layer 122 is formed on the exposed second face 164 of the core 120 of the first core panel 400, as illustrated in FIG. 4E. The second build-up layer 122 includes second build-up layer circuitry 184 that is electrically coupled to the first vias 128 formed in the core 120. The second build-up layer circuitry 184 is also electrically coupled to the vias 170 formed in the mold compound 210, thus electrically connecting the second build-up layer circuitry 184 to the IC device 132 disposed in the cavity 130 of the core 120. The second build-up layer circuitry 184 is also optionally electrically coupled to the vias 270 formed in the mold compound 210. The via 270 may be utilized to transfer data signals, power and/or ground to the IC die 102, or alternatively be used for channeling heat away from the IC device and out of the mold compound 210.

The second build-up layer circuitry 184 is formed by patterning metal layers disposed between dielectric layers 190. The patterned metal layers form the second built-up layer routing circuitry 184. The second built-up layer routing circuitry 184 is formed by connected lines 188 and vias 186 formed from the patterned metal layers of the second built-up layer 122.

The temporary carrier 402 is removed either before or after forming the second built-up layer 122. Scribe lanes 410 used to singulate the panels 400, 404 are illustrated in phantom in FIG. 4D.

At operation 312, the first build-up layer 118 is formed on the first face 162 of the core 120 of the first core panel 400 exposed by removal of the temporary carrier 402, as illustrated in FIG. 4F. The first build-up layer 118 includes first build-up layer circuitry 134 that is electrically coupled to the vias 128 formed through the core 120. The first build-up layer circuitry 134 is also electrically and mechanically coupled to contact pads exposed on the first face 156 of the IC device 132 disposed in the cavity 130 of the core 120. The first build-up layer circuitry 134 may also be electrically and mechanically coupled to the vias 272 formed through the mold compound 210 when the vias 272 are utilized to transmit any one or more of signals, power and/or ground to the IC die 102.

The first built-up layer 118 is formed by patterning metal layers disposed between dielectric layers 140. The patterned metal layers form the first built-up layer routing circuitry 134. The first built-up layer routing circuitry 134 is formed by connected lines 138 and vias 136 formed from the patterned metal layers of the first built-up layer 118.

At operation 314, the core panel 400 is diced along the scribe lanes 410 to singulate the core panel 400 into a plurality of individual substrates 104, as illustrated in FIG. 4F. The substrates 104 may be singulated using a wire saw or using another suitable technique.

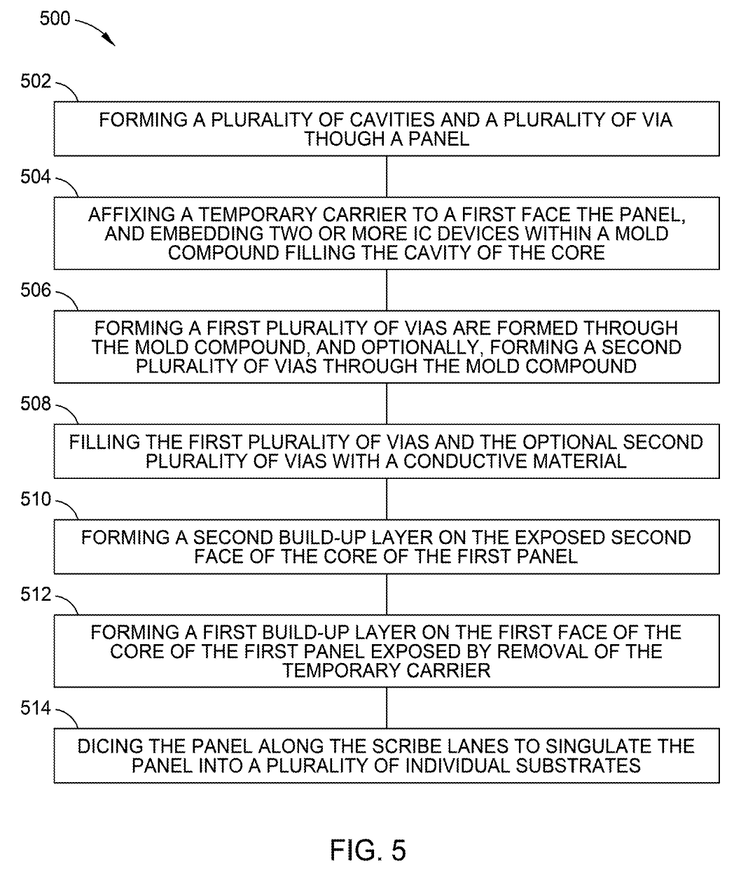

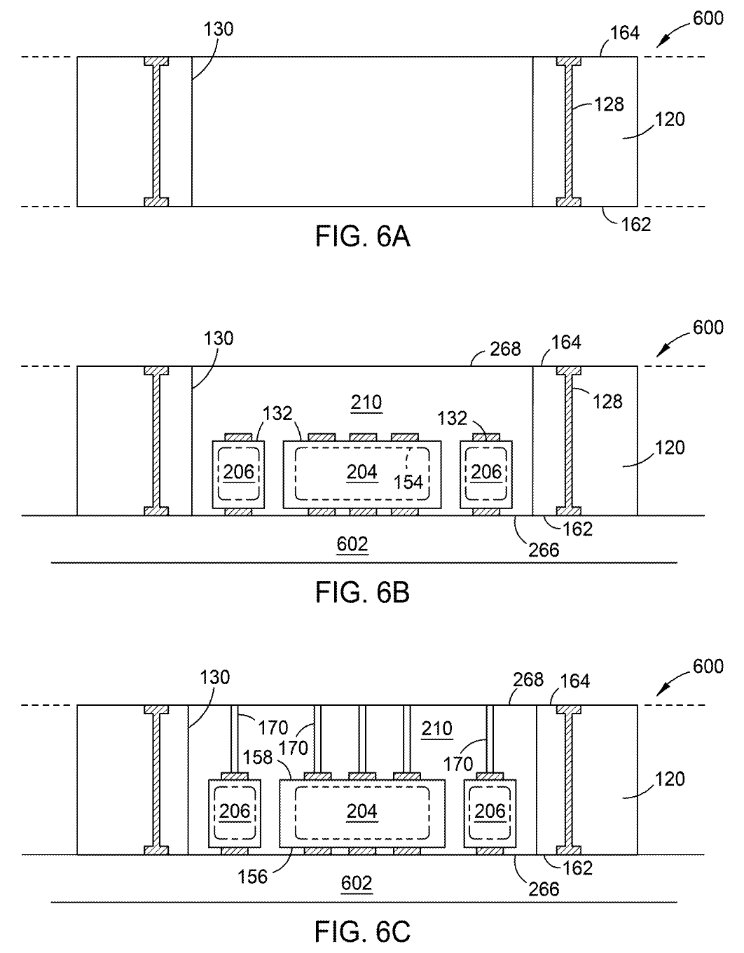

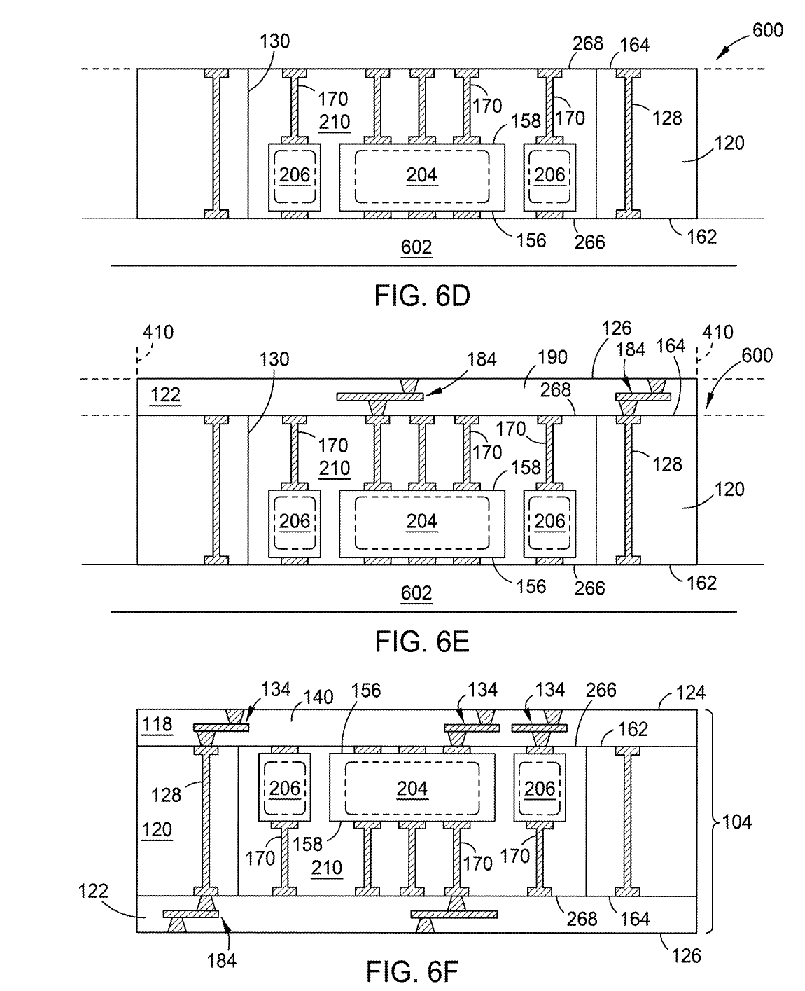

FIG. 5 is a block diagram of another method 600 for fabricating a substrate having two or more IC devices embedded in a core 120 of the substrate 104. FIGS. 6A-6E are schematic side views of another substrate having embedded IC devices during various stages of fabrication.

The method 500 begins at operation 502 by forming a plurality of cavities 130 though a core panel 600, as illustrated in FIG. 6A. A plurality of substrates 104 are singulated from the core panel 600, as later described below. The core panel 600 include faces 162, 164, that later become the faces of the core 120 of the substrate 104 after singulation of the core panel 600. Although only one cavity 130 is illustrated in FIG. 6A, it is to be understood that the core panel 600 extends to the laterally as represented by the dashed lines extending from the faces 162, 164, and that the additional cavities are formed in the same manner shown.

At operation 502, a plurality of vias 128 may be formed through the panel 128. The vias 128 are filled with a conductive material, such as copper, at operation 502 or other subsequent operation. Optionally, the plurality of vias 128 may be formed and/or filled at a different stage of fabrication.

At operation 504, a temporary carrier 602 is affixed to the first face 162 the core panel 600, and two or more IC devices 132 are embedded within the mold compound 210 by filling the cavity 130 of the core 120, as shown in FIG. 6B. The temporary carrier 602 may be an aluminum plate or other rigid plate. The IC device 132 may be first attached to the temporary carrier 602 by die attach tape or other temporary adhesive within the cavity 130 prior to filling the cavity 130 and partially encapsulating the IC devices 132 with the mold compound 210. Contact pads are also formed on the terminals of the IC device 132 prior to encapsulating the IC device 132 with the mold compound 210

The two or more IC devices 132 may be active and/or passive devices. One of the IC devices 132 shown in the cavity 130 depicted in FIG. 6B is an active device 204, while two of the IC devices 132 shown in the cavity 130 depicted in FIG. 6B are passive devices 206. Mold compound 210 is disposed in the cavities 130 to cover the IC devices 132 (i.e., the active and passive devices 204, 206).

At operation 506, a first plurality of vias 170 are formed through the mold compound 210, as illustrated in FIG. 6C. The first plurality of vias 170 may be mechanically through-holes (MTH), for example formed through the mold compound 210 by drilling or other suitable technique. The vias 170 extend from the second face 268 of the mold compound 210 to the contact pads formed on the second face 158 of the active device 204 and to the contact pads formed on the second face 158 of the passive devices 206.

Optionally at operation 506, a second plurality of vias 272 are formed through the mold compound 210, as illustrated in FIG. 6C. The second plurality of vias 272 may be formed by any suitable technique. The vias 272 extend from the second face 268 of the mold compound 210 to the first face 266 of the mold compound 210, forming a passage completely through the mold compound 210.

At operation 508, the first plurality of vias 170 and the optional second plurality of vias 272 are filled with a conductive material, as illustrated in FIG. 6D. The vias 170, 272 may be completely filed with copper or other conductive material. In one example, the sidewalls of the vias 170 and optionally the sidewalls of the vias 272, are plated.

The conductive filled vias 170 are electrically and mechanically coupled to the contact pads exposed on the second face 158 of the IC device 132. Thus, the conductive filled vias 170 are electrically coupled to the functional circuitry of the active device 204 and to the functional circuitry of the passive devices 206.

At operation 510, a second build-up layer 122 is formed on the exposed second face 164 of the core 120 of the first core panel 600, as illustrated in FIG. 6E. The second build-up layer 122 includes second build-up layer circuitry 184 that is electrically coupled to the first vias 128 formed in the core 120. The second build-up layer circuitry 184 is also electrically coupled to the vias 170 formed in the mold compound 210, thus electrically connecting the second build-up layer circuitry 184 to the IC device 132 (e.g., the active and passive IC devices 204, 206) disposed in the cavity 130 of the core 120. The second build-up layer circuitry 184 is also optionally electrically coupled to the vias 270 formed in the mold compound 210. The via 270 may be utilized to transfer data signals, power and/or ground to the IC die 102, or alternatively be used for channeling heat away from the IC device 132 and out of the mold compound 210.

The second build-up layer circuitry 184 is formed by patterning metal layers disposed between dielectric layers 190. The patterned metal layers form the second built-up layer routing circuitry 184. The second built-up layer routing circuitry 184 is formed by connected lines 188 and vias 186 formed from the patterned metal layers of the second built-up layer 122.

The first temporary carrier 602 is removed either before or after forming the second built-up layer 122. Scribe lanes 610 used to singulate the panels 600, 604 are illustrated in phantom in FIG. 6D.

At operation 512, the first build-up layer 118 is formed on the first face 166 of the core 120 of the first core panel 600 exposed by removal of the temporary carrier 602, as illustrated in FIG. 6F. The first build-up layer 118 includes first build-up layer circuitry 134 that is electrically coupled to the vias 128 formed through the core 120. The first build-up layer circuitry 134 is also electrically and mechanically coupled to contact pads exposed on the first face 156 of the IC device 132 (i.e., the contact pads of the active and passive devices 204, 206) disposed in the cavity 130 of the core 120. The first build-up layer circuitry 134 may also be electrically and mechanically coupled to the vias 272 formed through the mold compound 210 when the vias 272 are utilized to transmit any one or more of signals, power and/or ground to the IC die 102.

The first built-up layer 118 is formed by patterning metal layers disposed between dielectric layers 140. The patterned metal layers form the first built-up layer routing circuitry 134. The first built-up layer routing circuitry 134 is formed by connected lines 138 and vias 136 formed from the patterned metal layers of the first built-up layer 118.

At operation 514, the core panel 600 is diced along the scribe lanes 610 to singulate the core panel 600 into a plurality of individual substrates 104, as illustrated in FIG. 6F. The substrates 104 may be singulated using a wire saw or using another suitable technique.

Thus, the substrate architecture enables high-power integrated circuit packaging by enabling precise, scalable, and economical integration of both active and passive components directly within a singular monolithic core of the substrate. This architecture improves electrical performance and efficiency by positioning active elements closer to the die, enhances thermal management through thermally conductive materials and dedicated heat-dissipating structures, and increases manufacturing yield and reliability. Additionally, it leverages existing wafer-level processes to reduce complexity, cost, and design time, while supporting the growing demands of advanced computing systems for higher power density, improved component integration, and robust structural integrity.

The above described substrate architecture and method for fabricating the same may also be expressed in one or more of the following examples.

Example 1. An integrated circuit (IC) module including: a substrate core having a first face, a second face, and a cavity formed in the substrate core and open through the first and second faces of the substrate core; an IC device disposed in the cavity of the substrate core, the IC device having a first face and a second face, wherein a height of the IC device is less than a distance defined between the first and second faces of the substrate core; and mold compound disposed in the cavity of the substrate core, the mold compound having a first surface substantially coplanar with the first faces of the substrate core and the IC device, the mold compound having a second surface substantially coplanar with the second face of the substrate core.

Example 2. The IC module of Example 1, further including: a first plurality of conductive vias extending between the second face of the IC device and the second surface of the mold compound.

Example 3. The IC module of Example 2, further including: a second plurality of conductive vias extending between the first and second surfaces of the mold compound.

Example 4. The IC module of Example 3, wherein the first plurality of conductive vias further includes: mechanically formed holes filled with an electrically conductive material.

Example 5. The IC module of Example 1, further including: a passive IC device disposed in the mold compound adjacent the IC device, and a plurality of conductive vias extending between the passive IC device and the second surface of the mold compound.

Example 6. The IC module of Example 1, wherein the height of the IC device is less than or equal to about 800 µm.

Example 7. The IC module of Example 6, wherein the distance defined between the first and second faces of the substrate core is greater than or equal to 1000 µm.

Example 8. The IC module of Example 6, wherein the distance defined between the first and second faces of the substrate core is greater than or equal to 1600 µm.

Example 9. The IC module of Example 1, further including: first built-up layers formed over the IC device disposed in the cavity and the first face of the substrate core, the first built-up layers having substrate routing circuitry coupled to circuitry of the IC device.

Example 10. The IC module of Example 9, wherein the IC device embedded in the substrate core is an integrated voltage regulator.

Example 11. The IC module of Example 10, further including: a passive IC device embedded in the substrate core, the passive IC device one of a capacitor or an inductor.

Example 12. A chip package including: a substrate core having a first face, a second face, and a cavity formed in the substrate core and open through the first and second faces of the substrate core; an IC device disposed in the cavity of the substrate core, the IC device having a first face and a second face, wherein a height of the IC device is less than a distance defined between the first and second faces of the substrate core; mold compound disposed in the cavity of the substrate core, the mold compound having a first surface substantially coplanar with the first faces of the substrate core and the IC device, the mold compound having a second surface substantially coplanar with the second face of the substrate core; first built-up layers formed on the first face of the substrate core, the first built-up layers having substrate routing circuitry; and an integrated circuit (IC) die disposed on the first built-up layers, the IC die having functional circuitry coupled to the IC device through the first built-up layer routing circuitry.

Example 12A. The chip package of Example 11, wherein a thickness of the substrate core is 1.25 or more times greater than a height of the IC device.

Example 13. The chip package of Example 12, wherein the IC device embedded in the substrate core is an integrated voltage regulator.

Example 14. The chip package of Example 12, further including: a first plurality of conductive vias extending between the second face of the IC device and the second surface of the mold compound.

Example 15. The chip package of Example 14, further including: a second plurality of conductive vias extending between the first and second surfaces of the mold compound.

Example 16. The chip package of Example 14, wherein the first plurality of conductive vias further includes: mechanically formed holes filled with an electrically conductive material.

Example 17. The chip package of Example 12, further including: a passive IC device disposed in the mold compound adjacent the IC device, and a plurality of conductive vias extending between the passive IC device and the second surface of the mold compound.

Example 18. The IC module of Example 2, further including: a second plurality of conductive vias extending between the second face of the IC device and the second surface of the mold compound.

Example 19. A chip package including: a substrate having a core, the core having a cavity; an integrated voltage regulator embedded in the cavity of the core, a thickness of the core being about 2 or more times greater than a height of the integrated voltage regulator; an integrated circuit (IC) die disposed on the substrate and laterally overlapped with the integrated voltage regulator; mold compound disposed in the cavity of the core laterally between the substrate and the integrated voltage regular, the mold compound in contact with a face of the integrated voltage regulator facing away from the IC die; and a first plurality of conductive vias extending through the mold compound to the face of the integrated voltage regulator facing away from the IC die.

Example 20. The chip package of Example 19, further including: a passive IC device disposed in the mold compound adjacent the integrated voltage regulator, and a second plurality of conductive vias extending through the mold compound and coupled to the passive IC device.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different second-case letter suffix.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) module comprising:
a substrate core having a first face, a second face, and a cavity formed in the substrate core and open through the first and second faces of the substrate core;
an IC device disposed in the cavity of the substrate core, the IC device having a first face and a second face, wherein a height of the IC device is less than a distance defined between the first and second faces of the substrate core; and
mold compound disposed in the cavity of the substrate core, the mold compound having a first surface substantially coplanar with the first faces of the substrate core and the IC device, the mold compound having a second surface substantially coplanar with the second face of the substrate core.

2. The IC module of claim 1, further comprising:
a first plurality of conductive vias extending between the second face of the IC device and the second surface of the mold compound.

3. The IC module of claim 2, further comprising:
a second plurality of conductive vias extending between the first and second surfaces of the mold compound.

4. The IC module of claim 3, wherein the first plurality of conductive vias further comprises:
mechanically formed holes filled with an electrically conductive material.

5. The IC module of claim 1, further comprising:
a passive IC device disposed in the mold compound adjacent the IC device, and
a plurality of conductive vias extending between the passive IC device and the second surface of the mold compound.

6. The IC module of claim 1, wherein the height of the IC device is less than or equal to about 800 µm.

7. The IC module of claim 6, wherein the distance defined between the first and second faces of the substrate core is greater than or equal to 1000 µm.

8. The IC module of claim 6, wherein the distance defined between the first and second faces of the substrate core is greater than or equal to 1600 µm.

9. The IC module of claim 1, further comprising:
first built-up layers formed over the IC device disposed in the cavity and the first face of the substrate core, the first built-up layers having substrate routing circuitry coupled to circuitry of the IC device.

10. The IC module of claim 9, wherein the IC device embedded in the substrate core is an integrated voltage regulator.

11. The IC module of claim 10, further comprising:
a passive IC device embedded in the substrate core, the passive IC device one of a capacitor or an inductor.

12. A chip package comprising:
a substrate core having a first face, a second face, and a cavity formed in the substrate core and open through the first and second faces of the substrate core;
an IC device disposed in the cavity of the substrate core, the IC device having a first face and a second face, the substrate core having a thickness that is 1.25 or more times greater than a height of the IC device;
mold compound disposed in the cavity of the substrate core, the mold compound having a first surface substantially coplanar with the first faces of the substrate core and the IC device, the mold compound having a second surface substantially coplanar with the second face of the substrate core;
first built-up layers formed on the first face of the substrate core, the first built-up layers having substrate routing circuitry; and
an integrated circuit (IC) die disposed on the first built-up layers, the IC die having functional circuitry coupled to the IC device through the first built-up layer routing circuitry.

13. The chip package of claim 12, wherein the IC device embedded in the substrate core is an integrated voltage regulator.

14. The chip package of claim 12, further comprising:
a first plurality of conductive vias extending between the second face of the IC device and the second surface of the mold compound.

15. The chip package of claim 14, further comprising:
a second plurality of conductive vias extending between the first and second surfaces of the mold compound.

16. The chip package of claim 14, wherein the first plurality of conductive vias further comprises:
mechanically formed holes filled with an electrically conductive material.

17. The chip package of claim 12, further comprising:
a passive IC device disposed in the mold compound adjacent the IC device, and
a plurality of conductive vias extending between the passive IC device and the second surface of the mold compound.

18. The chip package of claim 12, further comprising:
a second plurality of conductive vias extending between the second face of the IC device and the second surface of the mold compound.

19. A chip package comprising:
a substrate having a core, the core having a cavity;
an integrated voltage regulator embedded in the cavity of the core, a thickness of the core being about 2 or more times greater than a height of the integrated voltage regulator;
an integrated circuit (IC) die disposed on the substrate and laterally overlapped with the integrated voltage regulator;
mold compound disposed in the cavity of the core laterally between the substrate and the integrated voltage regular, the mold compound in contact with a face of the integrated voltage regulator facing away from the IC die; and
a first plurality of conductive vias extending through the mold compound to the face of the integrated voltage regulator facing away from the IC die.

20. The chip package of claim 19, further comprising:
a passive IC device disposed in the mold compound adjacent the integrated voltage regulator, and
a second plurality of conductive vias extending through the mold compound and coupled to the passive IC device.
